(19) United States
(12) Patent Application Publication
(10) Pub. No.: US 2025/0006516 A1
(43) Pub. Date: Jan. 2, 2025

(54) SUBSTRATE SUPPORT AND PLASMA PROCESSING APPARATUS

(71) Applicant: Tokyo Electron Limited, Tokyo (JP)

(72) Inventor: Noriiki MASUDA, Miyagi (JP)

(73) Assignee: Tokyo Electron Limited, Tokyo (JP)

(21) Appl. No.: 18/754,202

(22) Filed: Jun. 26, 2024

(30) Foreign Application Priority Data
Jun. 27, 2023 (JP) 2023-104740

(51) Int. Cl. H01L 21/67; H01J 37/32; H01L 21/683; H01L 21/687

(52) U.S. Cl. CPC H01L 21/67017; H01J 37/32146; H01J 37/32174; H01J 37/3244; H01J 37/32724; H01L 21/6833; H01L 21/68721

(57) ABSTRACT

There is provided a substrate support that achieves both tilt controllability and uniformity of plasma density in a circumferential direction of a substrate. The substrate support includes: a substrate support surface for supporting the substrate; a ring support surface for supporting an edge ring; and an electrostatic chuck. The electrostatic chuck includes a first bias electrode and a second bias electrode, the first bias electrode is provided at least partially below the substrate support surface, the second bias electrode is provided at least partially below the ring support surface, and the first bias electrode and the second bias electrode overlap each other in a plan view in at least a partial region outside the substrate support surface and below the ring support surface.

### CROSS-REFERENCE TO RELATED APPLICATION

This application claims priority from Japanese Patent Application No. 2023-104740,filed on Jun. 27, 2023, the entire contents of which are incorporated herein by reference in their entirety.

### TECHNICAL FIELD

The present disclosure relates to a substrate support and a plasma processing apparatus.

### BACKGROUND

JP2021-158134A discloses a substrate support including a first region where a substrate is to be placed, and a second region where an edge ring is to be placed. The substrate support includes a first electrode provided in the first region for receiving a first electric bias, and a second electrode provided in the second region for receiving a second electric bias, and the second electrode extends below the first electrode to face the first electrode in the first region.

### CITATION LIST

### Patent Documents

Patent Document 1: JP2021-158134A

### SUMMARY

A technique according to the present disclosure provides a substrate support that achieves both tilt controllability and uniformity of plasma density in a circumferential direction of a substrate.

According to an aspect of the present disclosure, there is provided a substrate support including: a substrate support surface configured to support a substrate; a ring support surface configured to support an edge ring; and an electrostatic chuck. The electrostatic chuck includes a first bias electrode and a second bias electrode, the first bias electrode is provided at least partially below the substrate support surface, the second bias electrode is provided at least partially below the ring support surface, and the first bias electrode and the second bias electrode overlap each other in a plan view in at least a partial region outside the substrate support surface and below the ring support surface.

According to the present disclosure, it is possible to provide the substrate support that achieves both tilt controllability and uniformity of plasma density in a circumferential direction of the substrate.

### BRIEF DESCRIPTION OF DRAWINGS

FIG. 1 is a diagram illustrating a configuration example of a plasma processing system according to an embodiment.

FIG. 2 is a cross-sectional view illustrating a configuration example of a plasma processing apparatus according to the embodiment.

FIG. 3 is a cross-sectional view illustrating a configuration example of a substrate support according to a first embodiment.

FIG. 4 is a plan view illustrating the configuration example of the substrate support according to the first embodiment as viewed from above.

FIG. 5 is a cross-sectional view illustrating a configuration example of a substrate support according to a second embodiment.

FIG. 6 is a cross-sectional view illustrating a configuration example of a substrate support according to a third embodiment.

FIG. 7 is a cross-sectional view illustrating a configuration example of a substrate support according to a fourth embodiment.

FIG. 8 is a cross-sectional view illustrating a configuration example of a substrate support according to a fifth embodiment.

FIG. 9 is a cross-sectional view illustrating a configuration example of a substrate support according to a sixth embodiment.

FIG. 10 is a cross-sectional view illustrating a configuration example of a substrate support according to a seventh embodiment.

FIG. 11 is a cross-sectional view illustrating a configuration example of a substrate support according to an eighth embodiment.

FIG. 12 is a cross-sectional view illustrating a configuration example of a substrate support according to a ninth embodiment.

### DETAILED DESCRIPTION

In a process of manufacturing a semiconductor device, various processing steps are performed in which a processing module that accommodates a semiconductor substrate (hereinafter, referred to as a “substrate”) is brought into a pressure-reduced state, and the substrate is subjected to processing including plasma processing. The plurality of processing steps are performed using, for example, a substrate processing apparatus in which a plurality of processing modules are disposed around a common transport module.

In the processing module, the substrate is placed on a substrate support. In addition to the substrate, an edge ring is placed on the substrate support to surround a periphery of the substrate. A bias signal corresponding to a purpose of the plasma processing is supplied to the substrate or the edge ring placed on the substrate support.

JP2021-158134A discloses a substrate support including a first electrode provided in a first region where a substrate is to be placed, and a second electrode provided in a second region where an edge ring is to be placed, and the second electrode extends below the first electrode to face the first electrode in the first region. The first electrode and the second electrode are electrodes to which bias potentials are applied, and face each other within and at a lower side of the first region. It is described that by such a configuration in which the first electrode and the second electrode face each other within the first region, the first electrode and the second electrode are capacitively coupled, and a potential difference between the substrate and the edge ring is reduced. It is described that by reducing the potential difference, it is possible to appropriately control a tilt related to a plasma incident angle at a substrate peripheral edge portion.

However, when the present inventor intensively studied the configuration in which the first electrode and the second electrode face each other within the first region, that is, within the substrate, the following was found. That is, according to the configuration in which a part of the first electrode and a part of the second electrode face each other, when bias power is supplied to the electrodes during plasma generation, a boundary of plasma density may be formed between a first electrode side and a second electrode side above the part where the electrodes face each other. The boundary of plasma density is formed above the first electrode, that is, above the substrate. The boundary of plasma density formed above the substrate is susceptible to electromagnetic components of an electrostatic chuck (such as terminals connected to a chuck electrode and a bias electrode). Therefore, uniformity of the plasma density in a circumferential direction easily deteriorates above the substrate. The uniformity in the circumferential direction is improved when adopting a configuration in which a region of the part where the electrodes face each other is reduced, but in this case, there is a trade-off relationship that the above tilt controllability decreases.

Therefore, a technique according to the present disclosure provides a substrate support capable of preventing deterioration in uniformity in a circumferential direction above a substrate while maintaining tilt controllability of a substrate peripheral edge portion.

Hereinafter, a configuration of a substrate processing apparatus according to the present embodiment will be described with reference to the drawings. The same reference numerals will be given to elements having substantially the same functional configurations throughout the specification, and redundant description thereof will be omitted.

### Plasma Processing System

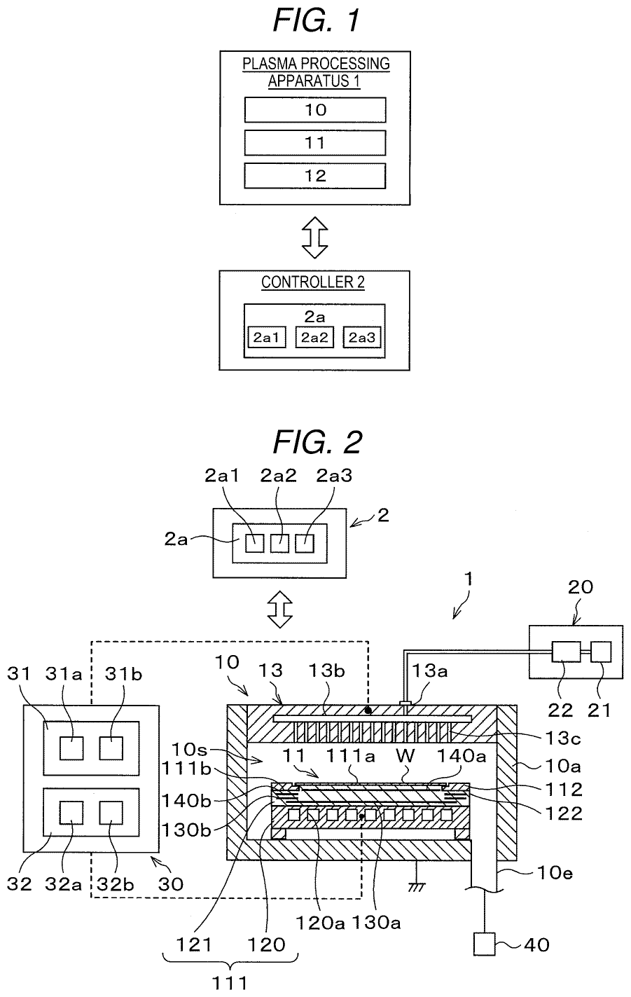

FIG. 1 is a diagram for explaining an example of a configuration of a plasma processing system. In an embodiment, a plasma processing system includes a plasma processing apparatus 1 and a controller 2. The plasma processing system is an example of a substrate processing system, and the plasma processing apparatus 1 is an example of a substrate processing apparatus. The plasma processing apparatus 1 includes a plasma processing chamber 10, a substrate support 11, and a plasma generator 12. The plasma processing chamber 10 has a plasma processing space. Further, the plasma processing chamber 10 has at least one gas supply port for supplying at least one processing gas into the plasma processing space, and at least one gas exhaust port for exhausting the gas from the plasma processing space. The gas supply port is connected to a gas supply 20 which will be described later, and the gas exhaust port is connected to an exhaust system 40 which will be described later. The substrate support 11 is disposed in the plasma processing space and has a substrate support surface 150a for supporting a substrate W, which will be described later.

The plasma generator 12 is configured to generate plasma from at least one processing gas supplied into the plasma processing space. The plasma formed in the plasma processing space may be capacitively coupled plasma (CCP), inductively coupled plasma (ICP), electron-cyclotron-resonance plasma (ECR plasma), helicon wave plasma (HWP), surface wave plasma (SWP), or the like. Further, various types of plasma generators, including an alternating current (AC) plasma generator and a direct current (DC) plasma generator, may be used. In one embodiment, an AC signal (AC power) used by the AC plasma generator has a frequency in a range of 100 kHz to 10 GHz. Accordingly, the AC signal includes a radio frequency (RF) signal and a microwave signal. In one embodiment, the RF signal has a frequency in a range of 100 kHz to 150 MHz.

The controller 2 processes computer-executable instructions for instructing the plasma processing apparatus 1 to execute various steps described herein below. The controller 2 may be configured to control the respective components of the plasma processing apparatus 1 to execute the various steps described herein below. In an embodiment, part or all of the controller 2 may be included in the plasma processing apparatus 1. The controller 2 may include a processor 2a1, a storage unit 2a2, and a communication interface 2a3. The controller 2 is implemented by, for example, a computer 2a. The processor 2a1 may be configured to read a program from the storage unit 2a2 and perform various control operations by executing the read program. The program may be stored in advance in the storage unit 2a2, or may be acquired via a medium when necessary. The acquired program is stored in the storage unit 2a2, and is read from the storage unit 2a2 and executed by the processor 2a1. The medium may be various storing media readable by the computer 2a, or may be a communication line connected to the communication interface 2a3. The processor 2a1 may be a Central Processing Unit (CPU). The storage unit 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN).

### Plasma Processing Apparatus

Hereinafter, a configuration example of a capacitively-coupled plasma processing apparatus 1 as an example of the plasma processing apparatus 1 will be described. FIG. 2 is a view for explaining an example of a configuration of the capacitively-coupled plasma processing apparatus 1.

The plasma processing apparatus 1 according to the present embodiment includes the plasma processing chamber 10, the gas supply 20, a power source 30, and the exhaust system 40. Further, the plasma processing apparatus 1 includes the substrate support 11 and a gas introduction unit. The gas introduction unit is configured to introduce at least one processing gas into the plasma processing chamber 10. The gas introduction unit includes a shower head 13. The substrate support 11 is disposed in the plasma processing chamber 10. The shower head 13 is disposed above the substrate support 11. In one embodiment, the shower head 13 constitutes at least a part of a ceiling of the plasma processing chamber 10. The plasma processing chamber 10 has a plasma processing space 10s defined by the shower head 13, a sidewall 10a of the plasma processing chamber 10, and the substrate support 11. The plasma processing chamber 10 is grounded. The shower head 13 and the substrate support 11 are electrically insulated from a housing of the plasma processing chamber 10.

The shower head 13 is configured to introduce at least one processing gas from the gas supply 20 into the plasma processing space 10s. The shower head 13 has at least one gas supply port 13a, at least one gas diffusion chamber 13b, and a plurality of gas introduction ports 13c. The processing gas supplied to the gas supply port 13a passes through the gas diffusion chamber 13b and is introduced into the plasma processing space 10s from the plurality of gas introduction ports 13c. Further, the shower head 13 includes at least one upper electrode. The gas introduction unit may include, in addition to the shower head 13, one or a plurality of side gas injectors (SGI) that are attached to one or a plurality of openings formed in the sidewall 10a.

The gas supply 20 may include at least one gas source 21 and at least one flow rate controller 22. In one embodiment, the gas supply 20 is configured to supply at least one processing gas from the respective corresponding gas sources 21 to the shower head 13 via the respective corresponding flow rate controllers 22. Each flow rate controller 22 may include, for example, a mass flow controller or a pressure-controlled flow rate controller. Further, the gas supply 20 may include at least one flow rate modulation device that modulates or pulses the flow rate of at least one processing gas.

The power source 30 includes an RF power source 31 coupled to the plasma processing chamber 10 via at least one impedance matching circuit. The RF power source 31 is configured to supply at least one RF signal (RF power) to at least one lower electrode and/or at least one upper electrode. As a result, plasma is formed from at least one processing gas supplied into the plasma processing space 10s. Accordingly, the RF power source 31 may function as at least a part of the plasma generator 12.

In one embodiment, a bias RF signal is supplied to two or more bias lower electrodes 130 to be described later, so that a bias potential is generated in the substrate W and an edge ring 113, ion components in the formed plasma are drawn into the substrate W, and a tilt in a substrate peripheral edge portion can be controlled. For convenience of description, the bias lower electrode 130 and other lower electrodes will be described separately in the specification. However, the bias lower electrode 130 may have a function as another lower electrode, and when simply referred to as a “lower electrode”, the bias lower electrode 130 is also included. The two or more bias lower electrodes 130 include a first bias electrode and a second bias electrode (to be described later), to which the same or different bias RF signals are supplied.

In one embodiment, the RF power source 31 includes a first RF generator 31a and a second RF generator 31b. The first RF generator 31a is configured to be coupled to at least one lower electrode and/or at least one upper electrode via at least one impedance matching circuit to generate a source RF signal (source RF power) for plasma generation. In one embodiment, the source RF signal has a frequency in the range of 10 MHz to 150 MHz. In one embodiment, the first RF generator 31a may be configured to generate a plurality of source RF signals having different frequencies. The generated one or more source RF signals are supplied to at least one lower electrode and/or at least one upper electrode.

Further, the second RF generator 31b is configured to be coupled to two or more bias lower electrodes 130 via at least one impedance matching circuit to generate a bias RF signal (bias RF power). A frequency of the bias RF signal may be the same as or different from a frequency of the source RF signal. In one embodiment, the bias RF signal has a lower frequency than the source RF signal. In one embodiment, the bias RF signal has a frequency in the range of 100 kHz to 60 MHz. In one embodiment, the second RF generator 31b may be configured to generate a plurality of bias RF signals having different frequencies. In this case, the plurality of generated bias RF signals are supplied to at least the first bias electrode or the second bias electrode (to be described later), or to both. Further, in various embodiments, at least one of the source RF signal and the bias RF signal may be pulsed.

In one embodiment, the power source 30 includes a DC power source 32 coupled to the plasma processing chamber 10. The DC power source 32 includes a first DC generator 32a and a second DC generator 32b. In one embodiment, the first DC generator 32a is configured to be connected to at least one lower electrode to generate a first DC signal. The generated first DC signal is applied to at least one lower electrode. In one embodiment, the second DC generator 32b is configured to be connected to at least one upper electrode to generate a second DC signal. The generated second DC signal is applied to at least one upper electrode.

In one embodiment, the first DC generator 32a supplies a bias DC signal serving as the first DC signal to the two or more bias lower electrodes 130 to be described later, so that a bias potential is generated in the substrate W and the edge ring 113, ion components in the formed plasma are drawn into the substrate W, and a tilt in a substrate peripheral edge portion can be controlled. In this case, the same or different bias DC signals are supplied to a first bias electrode 130a and a second bias electrode 130b to be described later.

In various embodiments, the first and second DC signals may be pulsed. In this case, the sequence of voltage pulses is applied to at least one lower electrode and/or at least one upper electrode. The voltage pulse may have a pulse waveform of a rectangle, a trapezoid, a triangle or a combination thereof. In one embodiment, a waveform generator for generating a sequence of voltage pulses from the DC signal is connected between the first DC generator 32a and at least one lower electrode. Accordingly, the first DC generator 32a and the waveform generator configure a voltage pulse generator. In a case where the second DC generator 32b and the waveform generator configure the voltage pulse generator, the voltage pulse generator is connected to at least one upper electrode. The voltage pulse may have a positive polarity or a negative polarity. Further, the sequence of the voltage pulses may include one or more positive voltage pulses and one or more negative voltage pulses in one cycle. The first and second DC generators 32a and 32b may be provided in addition to the RF power source 31, and the first DC generator 32a may be provided instead of the second RF generator 31b.

The exhaust system 40 may be connected to, for example, a gas exhaust port 10e disposed at a bottom portion of the plasma processing chamber 10. The exhaust system 40 may include a pressure adjusting valve and a vacuum pump. The pressure in the plasma processing space 10s is adjusted by the pressure adjusting valve. The vacuum pump may include a turbo molecular pump, a dry pump, or a combination thereof.

### Substrate Support

### First Embodiment

The substrate support 11 according to a first embodiment includes a main body 111 and a ring assembly 112. The main body 111 includes a central region 111a that is a central region for supporting the substrate W, and an annular region 111b that is an annular region for supporting the ring assembly 112. The annular region 111b of the main body 111 surrounds the central region 111a of the main body 111 in a plan view. The substrate W is disposed on the central region 111a of the main body 111 and the ring assembly 112 is disposed on the annular region 111b of the main body 111 to surround the substrate W on the central region 111a of the main body 111. The ring assembly 112 includes one or more annular members. In one embodiment, one or more annular members include one or more edge rings 113 and at least one cover ring. The edge ring 113 is formed of a conductive material or an insulating material, and the cover ring is formed of an insulating material.

The main body 111 includes a base 120 and an electrostatic chuck 121. The base 120 includes a conductive member. The conductive member of the base 120 may function as a lower electrode. The electrostatic chuck 121 is disposed on the base 120. The electrostatic chuck 121 includes a ceramic member 122. The ceramic member 122 includes the central region 111a and the annular region 111b. The electrostatic chuck 121 includes the bias lower electrode 130 and a chuck electrode 140 in the ceramic member 122. The bias lower electrode 130 includes the first bias electrode 130a provided below the substrate support surface 150a to be described later, and the second bias electrode 130b provided below a ring support surface 150b to be described later. The chuck electrode 140 includes a first chuck electrode 140a provided below the central region 111a and a second chuck electrode 140b provided below the annular region 111b. Other members that surround the electrostatic chuck 121, such as an annular electrostatic chuck and an annular insulating member, may have the annular region 111b. In this case, the ring assembly 112 may be disposed on the annular electrostatic chuck or the annular insulating member, or may be disposed on both the electrostatic chuck 121 and the annular insulating member.

In one embodiment, at least one other RF/DC electrode coupled to the RF power source 31 and/or the DC power source 32 described above may be disposed in the ceramic member 122. In this case, the other RF/DC electrodes function as lower electrodes. Further, in this case, the conductive member of the base 120 and at least one other RF/DC electrode may function as a plurality of lower electrodes.

Further, the substrate support 11 may include a temperature control module configured to adjust at least one of the electrostatic chuck 121, the ring assembly 112, and the substrate W to a target temperature. The temperature control module may include a heater, a heat transfer medium, a flow path 120a, or a combination thereof. A heat transfer fluid, such as brine or gas, flows through the flow path 120a. In one embodiment, the flow path 120a is formed in the base 120, and one or more heaters are disposed in the ceramic member 122 of the electrostatic chuck 121. Further, the substrate support 11 may include a heat transfer gas supply configured to supply a heat transfer gas to a gap between a back surface of the substrate W and the central region 111a.

### Bias Lower Electrode

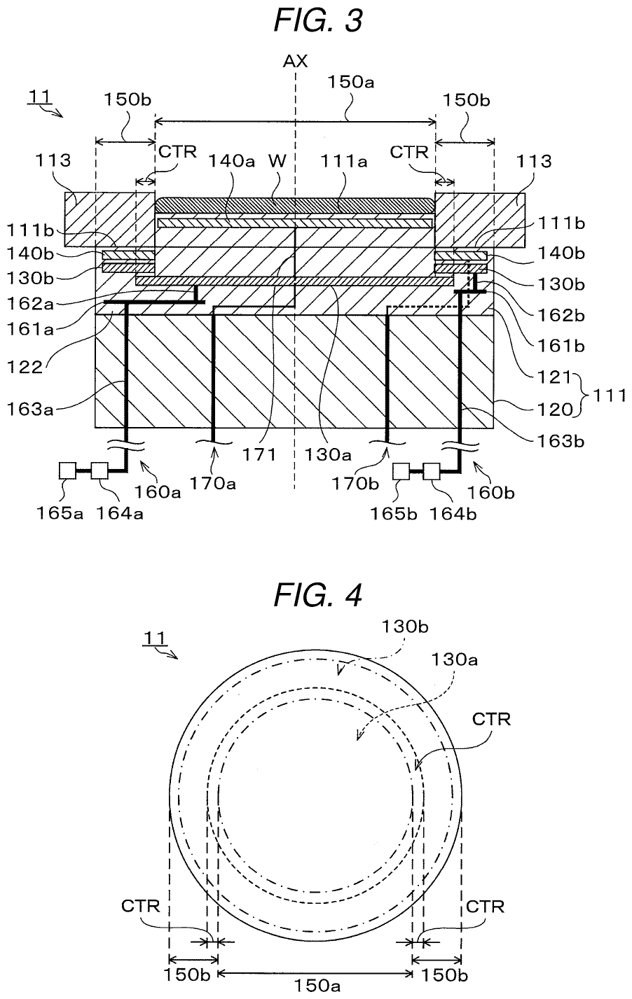

FIGS. 3 and 4 are a cross-sectional view and a plan view as viewed from above, respectively, schematically illustrating a configuration example of the bias lower electrode 130 according to the first embodiment. FIG. 3 illustrates an example of a state of the substrate support 11 on which the substrate W and the edge ring 113 are placed, and components of the ring assembly 112 other than the edge ring are not illustrated for convenience of description. In FIG. 4, the substrate W and the edge ring 113 are not illustrated for convenience of description.

As shown in FIG. 3, the substrate W is placed on the substrate support surface 150a, and the edge ring 113 is placed on the ring support surface 150b. The substrate support surface 150a is a surface including a region that overlaps the substrate W in the plan view when the substrate W is placed thereon. Further, the ring support surface 150b is a surface including a region that overlaps the edge ring 113 in the plan view when the edge ring 113 is placed thereon. In this configuration example, the substrate support surface 150a coincides with the central region 111a of the ceramic member 122, and the ring support surface 150b coincides with the annular region 111b of the ceramic member 122.

As shown in FIG. 4, the first bias electrode 130a, which is indicated by a portion surrounded by a dotted circle, has a substantially disk shape. Further, the second bias electrode 130b, which is indicated by a portion surrounded by two circles of dash-dotted lines, has a substantially annular shape. The first bias electrode 130a extends below the entire surface of the substrate support surface 150a and extends to a partial region outside the substrate support surface 150a and below the ring support surface 150b. Further, the second bias electrode 130b extends below the ring support surface 150b. With this configuration, the first bias electrode 130a and the second bias electrode 130b overlap each other in the plan view in a region outside the substrate support surface 150a and below the ring support surface 150b. The region is referred to as a crosstalk region CTR, and an overlapped configuration in the plan view in the crosstalk region CTR is referred to as “crosstalk outside the substrate”. Outside the substrate support surface 150a means outside a circle defining an outer periphery of the substrate support surface 150a in the plan view as shown in FIG. 4. In the example shown in FIG. 4, the circle defining the outer periphery of the substrate support surface 150a overlaps the circle indicated by the dash-dotted line inside the second bias electrode 130b, and thus outside the substrate support surface 150a means outside the circle indicated by the dash-dotted line inside the second bias electrode 130b.

Further, the substrate support 11 is provided with a first bias power supply 160a that supplies bias power to the first bias electrode 130a, and a second bias power supply 160b that supplies bias power to the second bias electrode 130b. The first bias power supply 160a includes a first connection layer 161a provided parallel to the first bias electrode 130a inside the ceramic member 122, and a plurality of first connectors 162a that connect the first connection layer 161a to the first bias electrode 130a at multiple points. Similarly, the second bias power supply 160b includes a second connection layer 161b provided parallel to the second bias electrode 130b inside the ceramic member 122, and a plurality of second connectors 162b that connect the second connection layer 161b to the second bias electrode 130b at multiple points. A first bias power source 165a is connected to the first connection layer 161a via a first supply terminal 163a and a circuit 164a. Further, a second bias power source 165b is connected to the second connection layer 161b via a second supply terminal 163b and a circuit 164b. In one embodiment, the first supply terminal 163a and the second supply terminal 163b are provided inside the base 120 and the ceramic member 122 outside the substrate support surface 150a.

In one embodiment, the first bias power source 165a, the second bias power source 165b, and the circuits 164a and 164b are included in the power source 30. In this case, the first bias power source 165a, the second bias power source 165b, and the circuits 164a and 164b may be included in the second RF generator 31b, and the circuits 164a and 164b may include impedance matching circuits.

Further, a first adsorption power supply 170a that supplies adsorption power to the first chuck electrode 140a and a second adsorption power supply 170b that supplies adsorption power to the second chuck electrode 140b are provided inside the base 120 and the ceramic member 122. The first adsorption power supply 170a includes a vertical connector 171 provided inside the ceramic member 122 and connected perpendicularly to the first chuck electrode 140a. In this configuration example, the vertical connector 171 is provided at a position overlapping a central axis AX of the main body 111.

According to the substrate support 11 in the configuration example described above, the crosstalk region CTR is located outside the substrate support surface 150a. Therefore, by controlling bias signals supplied to the first bias electrode 130a and the second bias electrode 130b, it is possible to control a tilt in a substrate peripheral edge portion during plasma generation above the crosstalk region CTR.

Further, when the bias signal is supplied to the bias lower electrode 130 during the plasma generation, a boundary of plasma density may be formed between a substrate upper side and an edge ring upper side above the crosstalk region CTR. In the crosstalk outside the substrate according to the present embodiment, a boundary of plasma density is formed above the second bias electrode 130b, that is, above the edge ring 113. As a result, uniformity of plasma density in a circumferential direction above the substrate can be improved.

Further, by connecting the first bias power supply 160a to the second bias power supply 160b at multiple points by the plurality of first connectors 162a and the plurality of second connectors 162b via the first connection layer 161a and the second connection layer 161b, and by providing the first supply terminal 163a and the second supply terminal 163b outside the substrate support surface 150a, electromagnetic influence of the terminals on the boundary of plasma density generated above the crosstalk region CTR can be minimized, and the uniformity of plasma density in the circumferential direction above the substrate and above the edge ring 113 can be further improved.

Further, by providing the vertical connector 171 at the position overlapping the central axis AX of the main body 111 in the first adsorption power supply 170a, the electromagnetic influence of the terminal on the uniformity of plasma density in the circumferential direction can be minimized.

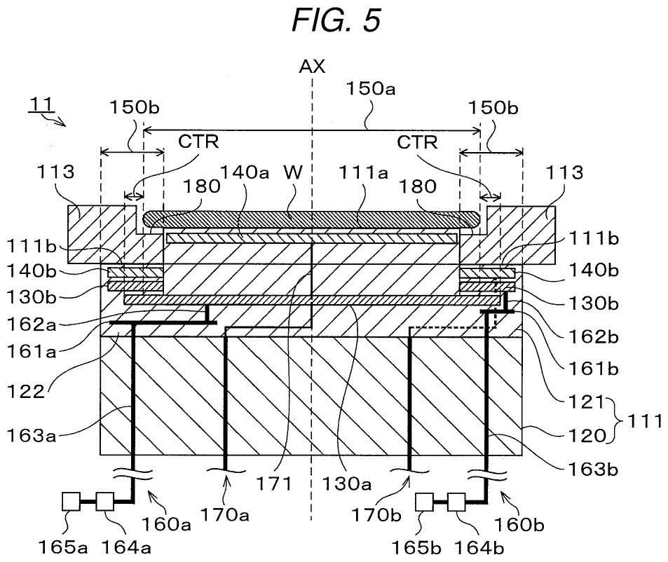

Hereinafter, various embodiments of the substrate support 11 will be described with reference to FIGS. 5 to 12. The various embodiments shown in FIGS. 3 to 12 are not mutually exclusive, and may be combined as desired, as long as the embodiments exhibit the above-described functions and effects regarding maintaining tilt controllability and improving the uniformity of plasma density in the circumferential direction.

### Second Embodiment

The substrate support 11 according to a second embodiment shown in FIG. 5 is different from the substrate support 11 according to the first embodiment in configurations of the edge ring 113 and the substrate support surface 150a. A recess 180 is formed in an upper surface of the edge ring 113 according to the second embodiment. The substrate support surface 150a is a region combining the central region 111a of the ceramic member 122 with the recess 180. With this configuration, the substrate support surface 150a and the ring support surface 150b partially overlap each other in a plan view. In this case, the crosstalk region CTR is outside the substrate support surface 150a. In the substrate support 11 according to the second embodiment, by configuring the crosstalk region CTR as described above, the same functions and effects as those in the first embodiment can be obtained.

### Third Embodiment

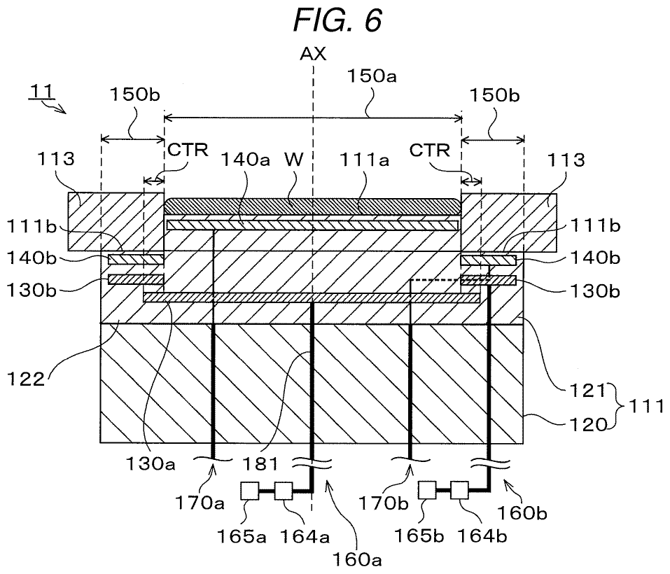

The substrate support 11 according to a third embodiment shown in FIG. 6 is different from the substrate support 11 according to the first embodiment in configurations of the first bias power supply 160a, the second bias power supply 160b, the first adsorption power supply 170a, and the second adsorption power supply 170b. Each of the first bias power supply 160a and the second bias power supply 160b according to the third embodiment does not include a connection layer and a plurality of connectors, and is connected to the bias electrode by one connection terminal. The first bias power supply 160a is located at a position overlapping the central axis AX of the main body 111. Further, the first adsorption power supply 170a and the second adsorption power supply 170b are located so that a vertical portion 181 provided inside the base 120 and indicated by a thick line in FIG. 6 is symmetrical with respect to the central axis AX. The second adsorption power supply 170b is provided with a horizontal portion indicated by a dotted line in FIG. 6 at the same height as the second bias electrode 130b. Further, the second bias power supply 160b and a connection terminal of the second adsorption power supply 170b, which is connected perpendicularly to the second chuck electrode 140b beyond the horizontal portion, are coaxially located. In the substrate support 11 according to the third embodiment, the connection layer, the plurality of connectors and the likes are not provided in the first bias power supply 160a and the second bias power supply 160b, and the terminals are arranged symmetrically in a circumferential direction. According to this arrangement, it is possible to minimize deterioration in uniformity in the circumferential direction due to electromagnetic influence of the terminal on a boundary of plasma density that may be formed above the crosstalk region CTR.

In the following fourth to sixth embodiments, configurations of the first bias power supply 160a, the second bias power supply 160b, the first adsorption power supply 170a, and the second adsorption power supply 170b are the same as those in the third embodiment for convenience of description, although not limited thereto.

### Fourth Embodiment

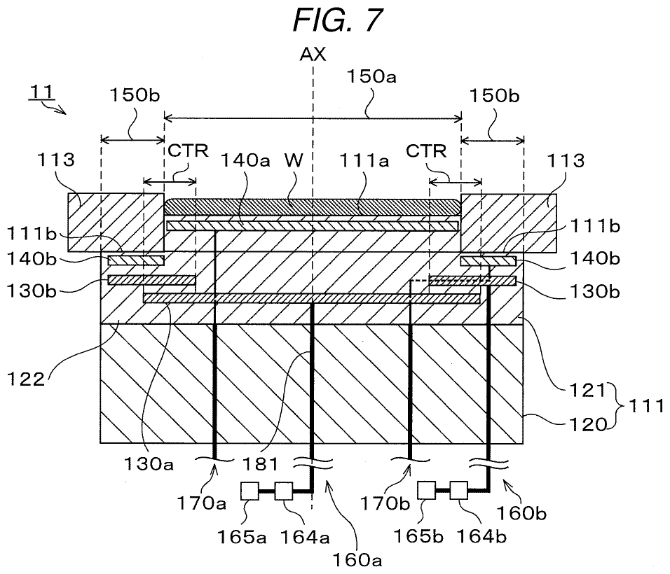

The substrate support 11 according to a fourth embodiment shown in FIG. 7 is different from the substrate support 11 according to the third embodiment in a configuration of the second bias electrode 130b. The second bias electrode 130b according to the fourth embodiment extends not only below the ring support surface 150b but also below the substrate support surface 150a. With this configuration, the crosstalk region CTR is located below across both the substrate support surface 150a and the ring support surface 150b. In the substrate support 11 according to the fourth embodiment, by configuring the crosstalk region CTR as described above, a boundary of plasma density that may be formed above the crosstalk region CTR is also formed above the substrate W. Even in this case, uniformity in a circumferential direction can be improved through the same operations and effects as in the third embodiment, compared to a case where at least the entire crosstalk region CTR is located inside the substrate support surface 150a.

### Fifth Embodiment

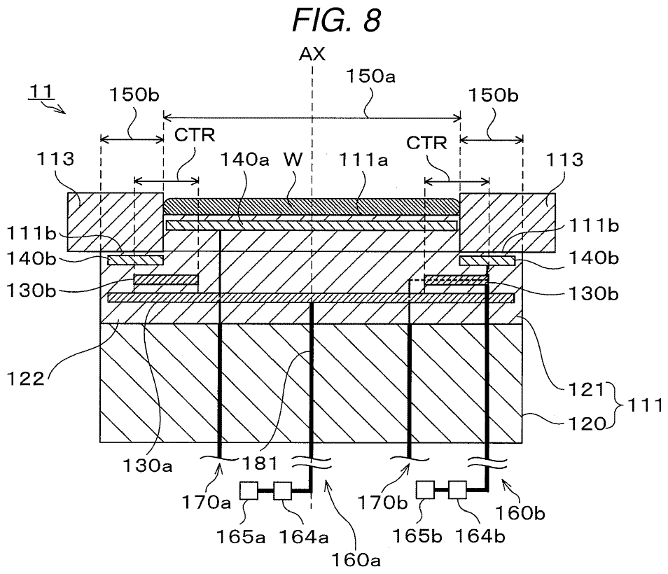

The substrate support 11 according to a fifth embodiment shown in FIG. 8 is different from the substrate support 11 according to the third embodiment in configurations of the first bias electrode 130a and the second bias electrode 130b. The first bias electrode 130a according to the fifth embodiment extends not only below the substrate support surface 150a but also below the entire surface of the ring support surface 150b. Further, the second bias electrode 130b extends not only below the ring support surface 150b but also below the substrate support surface 150a. The second bias electrode 130b does not extend below the entire surface of the ring support surface 150b, but extends below only a partial region. In the substrate support 11 according to the fifth embodiment, by providing the first bias power supply 160a extending below the entire surfaces of both the substrate support surface 150a and the ring support surface 150b, uniformity of plasma density in a circumferential direction above both the substrate support surface 150a and the ring support surface 150b can be improved. Further, tilt controllability on the substrate peripheral edge portion can be maintained by the crosstalk region CTR where the first bias power supply 160a overlaps the second bias electrode 130b extending below at least a part of the ring support surface 150b in a plan view.

### Sixth Embodiment

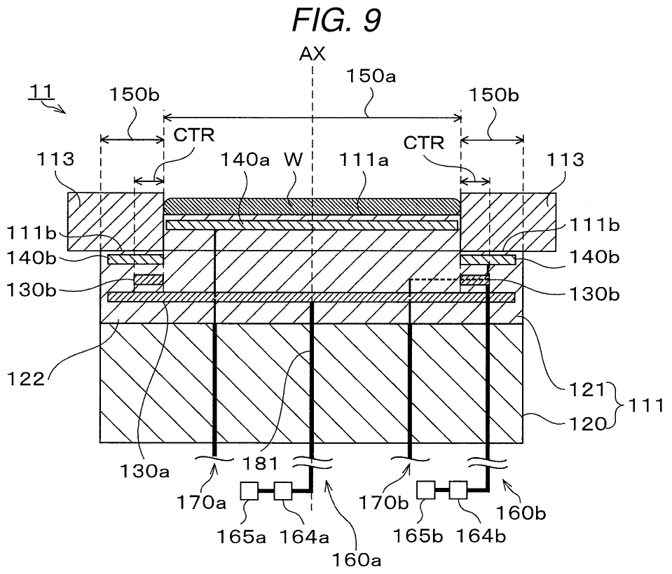

The substrate support 11 according to a sixth embodiment shown in FIG. 9 is different from the substrate support 11 according to the third embodiment in configurations of the first bias electrode 130a and the second bias electrode 130b. The first bias electrode 130a according to the sixth embodiment is the same as that according to the fifth embodiment. The second bias electrode 130b extends below only a part of the ring support surface 150b. In the substrate support 11 according to the sixth embodiment, in addition to obtaining the same operations and effects as those of the substrate support 11 according to the fifth embodiment, since there is no crosstalk region inside the substrate support surface 150a, no boundary of plasma density is formed above the substrate support surface 150a, and uniformity in a circumferential direction above the substrate can be improved.

### Seventh Embodiment

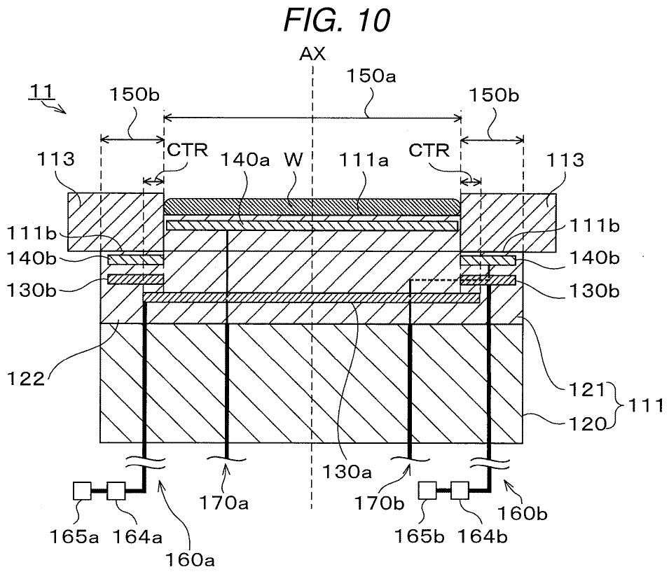

The substrate support 11 according to a seventh embodiment shown in FIG. 10 is different from the substrate support 11 according to the third embodiment in a configuration of the first bias power supply 160a. The first bias power supply 160a according to the seventh embodiment is located outside the substrate support surface 150a and is symmetrical with the second bias power supply 160b across the central axis AX. In the substrate support 11 according to the seventh embodiment, a connection layer, a plurality of connectors, and the likes are not provided in the first bias power supply 160a and the second bias power supply 160b, and the terminals are arranged symmetrically in a circumferential direction. According to this arrangement, it is possible to minimize deterioration in uniformity in the circumferential direction due to electromagnetic influence of the terminal on a boundary of plasma density that may be formed above the crosstalk region CTR.

### Eighth Embodiment

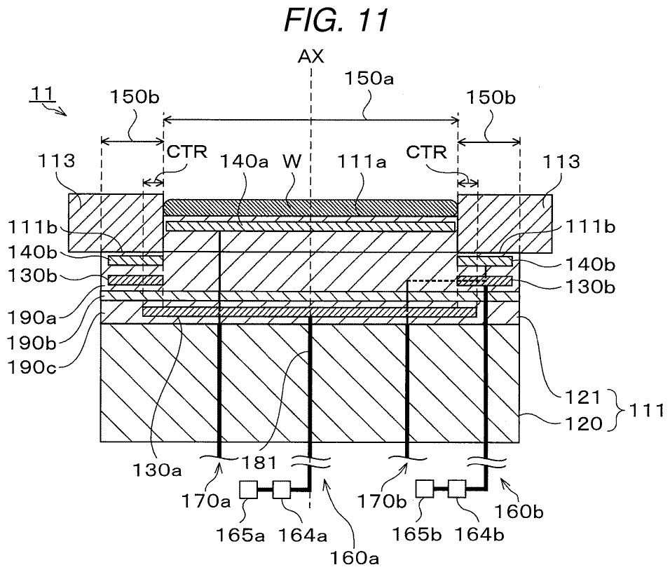

The substrate support 11 according to an eighth embodiment shown in FIG. 11 is different from the substrate support 11 according to the third embodiment in a configuration of the ceramic member 122 of the electrostatic chuck 121. The ceramic member 122 according to the eighth embodiment includes a first layer 190a, a second layer 190b, and a third layer 190c in this order from an upper side toward a lower side. A first ceramic material forming the first layer 190a and the third layer 190c and a second ceramic material forming the second layer 190b are different materials. The first layer 190a constitutes the substrate support surface 150a and the ring support surface 150b, and includes the second bias electrode 130b. Further, the third layer 190c includes the first bias electrode 130a. In other words, the ceramic member 122 has a configuration in which the first layer 190a including the second bias electrode 130b and the third layer 190c including the first bias electrode 130a are separated by the second layer 190b. In the substrate support 11 according to the eighth embodiment, a desired configuration can be obtained by, for example, adjusting a distance between the first bias electrode 130a and the second bias electrode 130b, adjusting a thickness of the second layer 190b, or selecting the second ceramic material. Specifically, a capacitance ratio of a capacitance between the base 120 and the substrate W to a capacitance between the base 120 and the edge ring 113 can be a desired value. Further, a capacitance ratio of a capacitance between the first bias electrode 130a and the substrate W to a capacitance between the second bias electrode 130b and the edge ring 113 can be a desired value. As an example, the capacitance ratios are both 1:1.

### Ninth Embodiment

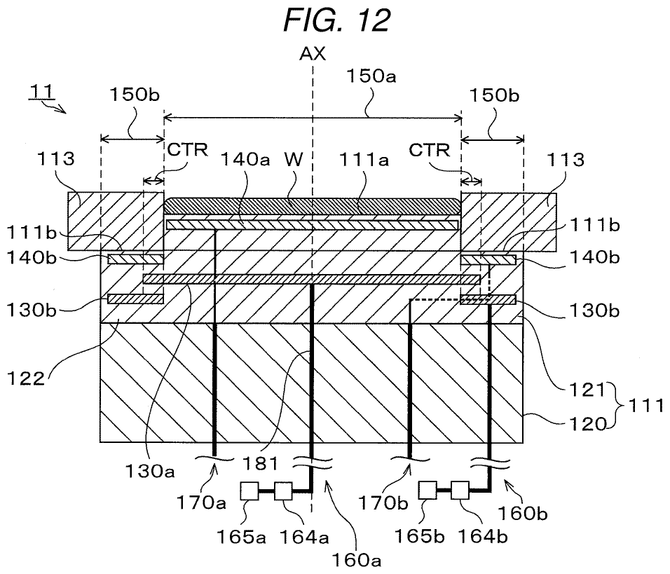

The substrate support 11 according to a ninth embodiment shown in FIG. 12 is different from the substrate support 11 according to the third embodiment in configurations of the first bias electrode 130a and the second bias electrode 130b. Inside the ceramic member 122 according to the ninth embodiment, the first bias electrode 130a is provided above the second bias electrode 130b. With this configuration, the crosstalk region CTR can also be provided outside the substrate. In the substrate support 11 according to the ninth embodiment, by configuring the crosstalk region CTR as described above, the same functions and effects as those in the third embodiment can be obtained.

It shall be understood that the embodiments disclosed herein are illustrative and are not restrictive in all aspects. The embodiment described above may be omitted, replaced, or modified in various forms without departing from the scope and spirit of the appended claims. For example, the components of the embodiments described above may be combined as desired. From the desired combination, functions and effects of each component related to the combination can be obtained as a matter of course, and other functions and effects apparent to those skilled in the art can be obtained from the description herein.

The effects described herein are merely illustrative or exemplary, and are not limited. In other words, the technique according to the present disclosure may have other effects apparent to those skilled in the art from the description herein, in addition to or in place of the effects described above.

The following configuration examples also fall within the technical scope of the present disclosure.
(1) A substrate support includes:
a substrate support surface configured to support a substrate;
a ring support surface configured to support an edge ring; and
an electrostatic chuck.
The electrostatic chuck includes a first bias electrode and a second bias electrode, the first bias electrode is provided at least partially below the substrate support surface, the second bias electrode is provided at least partially below the ring support surface, and
the first bias electrode and the second bias electrode overlap each other in a plan view in at least a partial region outside the substrate support surface and below the ring support surface.
(2) In the substrate support according to (1),
the first bias electrode extends below an entire surface of the substrate support surface and extends to at least a partial region outside the substrate support surface and below the ring support surface.
(3) In the substrate support according to (1) or (2),
the first bias electrode is provided below the second bias electrode.
(4) The substrate support according to any one of (1) to (3) further includes:
a first bias power supply configured to supply first bias power to the first bias electrode.

A connection point between the first bias electrode and the first bias power supply is provided outside the substrate support surface in the plan view.

(5) The substrate support according to any one of (1) to (3) further includes:
a first bias power supply configured to supply first bias power to the first bias electrode; and
a second bias power supply configured to supply second bias power to the second bias electrode.

The first bias power supply includes
a first connection layer provided parallel to the first bias electrode, and
a plurality of first connectors provided between the first connection layer and the first bias electrode, and
the second bias power supply includes
   a second connection layer provided parallel to the second bias electrode, and
   a plurality of second connectors provided between the second connection layer and the second bias electrode.
(6) In the substrate support according to any one of (1) to (5),
the electrostatic chuck includes
   a chuck electrode provided below the substrate support surface, and
   an adsorption power supply configured to supply adsorption power to the chuck electrode,
the adsorption power supply includes a vertical portion extending perpendicularly to the substrate support surface and connected to the chuck electrode, and
the vertical portion overlaps a central axis of the substrate support in the plan view.
(7) The substrate support according to any one of (1) to (6) further includes:
a base provided below the electrostatic chuck.

A capacitance ratio of a capacitance between the base and the substrate to a capacitance between the base and the edge ring is 1:1, and
a capacitance ratio of a capacitance between the first bias electrode and the substrate to a capacitance between the second bias electrode and the edge ring is 1:1.
(8) In the substrate support according to any one of (1) to (7),
the electrostatic chuck includes a first layer, a second layer, and a third layer in this order from an upper side toward a lower side,
a first dielectric material forming the first layer and the third layer and a second dielectric material forming the second layer are different materials,
the first layer constitutes the substrate support surface and the ring support surface, and includes the second bias electrode, and
the third layer includes the first bias electrode.
(9) A plasma processing apparatus includes:
a substrate support including a substrate support surface configured to support a substrate, a ring support surface configured to support an edge ring, and an electrostatic chuck.

The electrostatic chuck includes a first bias electrode and a second bias electrode,
the first bias electrode is provided at least partially below the substrate support surface,
the second bias electrode is provided at least partially below the ring support surface, and
the first bias electrode and the second bias electrode overlap each other in a plan view in at least a partial region outside the substrate support surface and below the ring support surface.
(10) The plasma processing apparatus according to (9) further includes:
a first bias power source configured to supply first bias power to the first bias electrode; and
a second bias power source configured to supply second bias power to the second bias electrode.
(11) In the plasma processing apparatus according to (8) or (9),
the first bias power source and the second bias power source are DC power sources, and
the first bias power and the second bias power are DC power.

1. A substrate support comprising:
a substrate support surface configured to support a substrate;
a ring support surface configured to support an edge ring; and
an electrostatic chuck including:
a first bias electrode; and
a second bias electrode,
wherein
the first bias electrode is provided at least partially below the substrate support surface,
the second bias electrode is provided at least partially below the ring support surface, and
the first bias electrode and the second bias electrode overlap each other in a plan view in at least a partial region outside the substrate support surface and below the ring support surface.

2. The substrate support according to claim 1, wherein
the first bias electrode extends below an entirety of the substrate support surface and to region outside the substrate support surface that is below the ring support surface.

3. The substrate support according to claim 1, wherein
the first bias electrode is provided below the second bias electrode.

4. The substrate support according to claim 1, further comprising:
a first bias power supply configured to supply first bias power to the first bias electrode, wherein
a connection point between the first bias electrode and the first bias power supply is provided outside the substrate support surface in the plan view.

5. The substrate support according to claim 1, further comprising:
a first bias power supply configured to supply first bias power to the first bias electrode; and
a second bias power supply configured to supply second bias power to the second bias electrode, wherein
the first bias power supply includes
a first connection layer provided parallel to the first bias electrode, and
a plurality of first connectors provided between the first connection layer and the first bias electrode, and
the second bias power supply includes
a second connection layer provided parallel to the second bias electrode, and
a plurality of second connectors provided between the second connection layer and the second bias electrode.

6. The substrate support according to claim 5, wherein
the electrostatic chuck includes
a chuck electrode provided below the substrate support surface, and
an adsorption power supply configured to supply adsorption power to the chuck electrode,
the adsorption power supply includes a vertical portion extending transversely to the substrate support surface and connected to the chuck electrode, and
the vertical portion overlaps a central axis of the substrate support in the plan view.

7. The substrate support according to claim 1, further comprising:
a base provided below the electrostatic chuck, wherein
a capacitance ratio of a capacitance between the base and the substrate to a capacitance between the base and the edge ring is 1:1, and
a capacitance ratio of a capacitance between the first bias electrode and the substrate to a capacitance between the second bias electrode and the edge ring is 1:1.

8. The substrate support according to claim 7, wherein
the electrostatic chuck includes a first layer, a second layer, and a third layer, the second layer being disposed between the first layer and the third layer, the first layer including an upper side of the electrostatic chuck and the third layer including a lower side of the electrostatic chuck,
a first dielectric material forms the first layer and the third layer,
a second dielectric material forms the second layer, the first dielectric material being different from the second dielectric material,
the first layer constitutes the substrate support surface and the ring support surface, and includes the second bias electrode, and
the third layer includes the first bias electrode.

9. A plasma processing apparatus comprising:
a plasma processing chamber;
a gas supply configured to supply gas to the plasma processing chamber; and
a substrate support including
a substrate support surface configured to support a substrate;
a ring support surface configured to support an edge ring; and
an electrostatic chuck including:
a first bias electrode; and
a second bias electrode,
wherein
the first bias electrode is provided at least partially below the substrate support surface,
the second bias electrode is provided at least partially below the ring support surface, and
the first bias electrode and the second bias electrode overlap each other in a plan view in at least a partial region outside the substrate support surface and below the ring support surface.

10. The plasma processing apparatus according to claim 9, further comprising:
a first bias power source configured to supply first bias power to the first bias electrode; and
a second bias power source configured to supply second bias power to the second bias electrode.

11. The plasma processing apparatus according to claim 10, wherein
the first bias power source and the second bias power source are DC power sources, and
the first bias power and the second bias power are DC power.

12. The plasma processing apparatus according to claim 9, wherein
the first bias electrode extends below an entirety of the substrate support surface and to region outside the substrate support surface that is below the ring support surface.

13. The plasma processing apparatus according to claim 9, wherein
the first bias electrode is provided below the second bias electrode.

14. The plasma processing apparatus according to claim 9, further comprising:
a first bias power supply configured to supply first bias power to the first bias electrode, wherein
a connection point between the first bias electrode and the first bias power supply is provided outside the substrate support surface in the plan view.

15. The plasma processing apparatus according to claim 9, wherein
the first bias power supply includes
a first connection layer provided parallel to the first bias electrode, and
a plurality of first connectors provided between the first connection layer and the first bias electrode, and
the second bias power supply includes
a second connection layer provided parallel to the second bias electrode, and
a plurality of second connectors provided between the second connection layer and the second bias electrode.

16. The plasma processing apparatus according to claim 15, wherein
the electrostatic chuck includes
a chuck electrode provided below the substrate support surface, and
an adsorption power supply configured to supply adsorption power to the chuck electrode,
the adsorption power supply includes a vertical portion extending transversely to the substrate support surface and connected to the chuck electrode, and
the vertical portion overlaps a central axis of the substrate support in the plan view.

17. The plasma processing apparatus according to claim 9, further comprising:
a base provided below the electrostatic chuck, wherein
a capacitance ratio of a capacitance between the base and the substrate to a capacitance between the base and the edge ring is 1:1.

18. The plasma processing apparatus according to claim 9, wherein a capacitance ratio of a capacitance between the first bias electrode and the substrate to a capacitance between the second bias electrode and the edge ring is 1:1.

19. The plasma processing apparatus according to claim 18, wherein
the electrostatic chuck includes a first layer, a second layer, and a third layer, the second layer being disposed between the first layer and the third layer, the first layer including an upper side and the third layer including a lower side.

20. The plasma processing apparatus according to claim 19, wherein
a first dielectric material forms the first layer and the third layer,
a second dielectric material forms the second layer, the first dielectric material being different from the second dielectric material,
the first layer constitutes the substrate support surface and the ring support surface, and includes the second bias electrode, and
the third layer includes the first bias electrode.
